(19) United States
(12) Patent Application Publication
(10) Pub. No.: US 2026/0198002 A1
(43) Pub. Date: Jul. 9, 2026

(54) MICROELECTRONIC DEVICES HAVING SPLIT SOURCE DESIGNS, AND RELATED METHODS AND ELECTRONIC SYSTEMS

(71) Applicant: Micron Technology, Inc., Boise, ID (US)

(72) Inventors: Lorenzo Pedrazzetti, Soncino (IT); Paolo Tessariol, Arcore (IT); Nicolo' Gravellini, Milan (IT)

(21) Appl. No.: 19/414,032

(22) Filed: Dec. 9, 2025

Related U.S. Application Data
(60) Provisional application No. 63/742,737, filed on Jan. 7, 2025.

(51) Int. Cl. H10B 41/35; H10B 41/27; H10B 43/27; H10B 43/35

(52) U.S. Cl. CPC H10B 41/35; H10B 41/27; H10B 43/27; H10B 43/35

(57) ABSTRACT

A microelectronic device includes a stack structure including tiers vertically stacked relative to one another and respectively including conductive material vertically neighboring insulative material. The stack structure includes two memory array regions and a staircase region horizontally between the two memory array regions. The microelectronic device also includes strings of memory cells within horizontal areas of and vertically extending through the two memory array regions of the stack structure. A source tier is vertically offset from the stack structure and includes source structures in contact with the strings of memory cells. A horizontal area of the staircase region of the stack structure is substantially free of the source structures. Memory devices and electronic systems are also described.

### CROSS-REFERENCE TO RELATED APPLICATIONS

This application claims the benefit under 35 U.S.C. § 119(e) of U.S. Provisional Patent Application Ser. No. 63/742,737, filed Jan. 7, 2025, the disclosure of which is hereby incorporated herein in its entirety by this reference.

### TECHNICAL FIELD

This disclosure relates generally to the field of microelectronic device design and fabrication. More specifically, the disclosure relates to microelectronic devices including a split source architectures, and to related memory devices and electronic systems.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in tiers of conductive structures (e.g., word lines) and dielectric materials at each junction of the vertical memory strings and the conductive structures. Such a configuration permits a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors. However, conventional 3D memory array architectures can suffer from inefficiencies associated with the configuration of a source plate coupled to the vertical memory strings.

### BRIEF DESCRIPTION OF THE DRAWINGS

FIG. 1 schematically illustrates a microelectronic device structure, in accordance with one embodiment of the disclosure.

FIG. 2 schematically illustrates a microelectronic device structure, in accordance with one embodiment of the disclosure.

FIG. 3 shows a simplified, partial vertical cross-sectional view of a microelectronic device structure, in accordance with one embodiment of the disclosure.

FIG. 4 shows a simplified, partial vertical cross-sectional view of a microelectronic device structure, in accordance with one embodiment of the disclosure.

FIG. 5 shows a simplified, partial vertical cross-sectional view of a microelectronic device structure, in accordance with one embodiment of the disclosure.

FIG. 6 schematically illustrates an electronic system, in accordance with one embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

In memory devices (e.g., NAND Flash memory devices), memory arrays may be divided into planes of blocks respectively including an array of memory cells (e.g., non-volatile memory cells, such as charge-trapping memory cells or floating-gate memory cells) therein. The blocks within an individual plane may share digit lines (e.g., data lines, bitlines) with one another. The digit lines may extend horizontally orthogonal to local word lines of the blocks of the plane. In such memory devices, a global source plate may horizontally extend (e.g., in an X-direction and a Y-direction) to fit the horizontal area of a respective plane. For example, a global source plate may extend the full horizontal area occupied by all of the blocks of a respective plane.

During a random read operation, only part of a page may need to be read (e.g., only 8 KB or 4 KB pillars are read). However, in 3D NAND, an individual global word line may be electrically continuous across an entire plane. During a read operation, the entire global word line is typically biased, even if only a portion of the memory cells along that word line need to be read. This results in a large capacitive load, as the full length of the word line must be charged and discharged. The total capacitive load during the read operation is therefore proportional to the full page size, which can waste energy when only part of a page needs to be read (e.g., operations reading less than 16 KB). This large capacitive load also increases the time required to raise the word line voltage to the desired level, potentially increasing read latency.

In embodiments described herein, a plane of memory (e.g., NAND flash memory) may be structured with a source plate that does not extend a full length of a plane in a direction parallel with the word lines. For example, the source plate may be configured to be split, such that the source place does not horizontally extend through at least part of a staircase region of the plane. Such a split configuration of the source plate may reduce the capacitive load of the word line drivers. By reducing the capacitive load during a random read operation by boosting pillars that do not need to be read, the overall performance may be improved due to faster word line raise times and lower latencies.

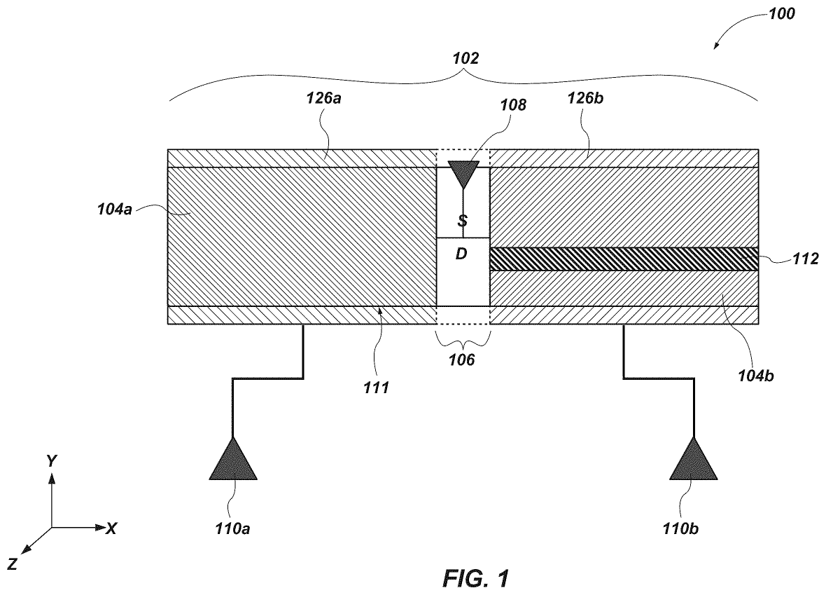

FIG. 1 illustrates a schematic of a microelectronic device structure 100, according to one embodiment of the disclosure. The microelectronic device structure 100 includes a plane 102. The plane 102 may extend horizontally in a first direction (e.g., Y-direction) and includes a number of blocks 111 of memory arrays. Different groups of the blocks 111 may respectively share a group of data lines (e.g., digit lines, bit lines). The blocks 111 of a given group of blocks 111 may extend in parallel with one another in a second direction (e.g., X-direction). Each block 111 may include a stack of conductive lines (e.g., word lines, select lines) operatively associated with an array of vertically extending strings of memory cells (e.g., vertically extending strings of non-volatile memory cells, such as vertically extending strings of charge-trapping memory cells or vertically extending strings of floating-gate memory cells) of the block 111. As shown in FIG. 1, the microelectronic device structure 100 may include a first memory cell region 104a and a second memory cell region 104b separated by a staircase region 106. Individual blocks 111 of the microelectronic device structure 100 may have a central, bi-directional staircase structure (“CBSC”) horizontally overlapping (e.g., in the X-direction) the staircase region 106 of the microelectronic device structure 100. The CBSC is horizontally located, in the X-direction, in the center or between two memory cell sections of the block 111 that respectively horizontally overlap one of the first memory cell region 104a and the second memory cell region 104b of the microelectronic device structure 100.

The microelectronic device structure 100 may further include a first source structure 126a within a horizontal area of the first memory cell region 104a, and a second source structure 126b within a horizontal area of the second memory cell region 104b. In this example, the first source structure 126a is electrically separated from the second source structure 126b. As compared to conventional source structures that would extend continuously throughout the plane 102, a source structure is not provided within at least a portion of the staircase region 106, effectively splitting (e.g., physically separating, electrically separating) the first source structure 126a from the second source structure 126b. In this example, the first source structure 126a and the second source structure 126b are both entirely absent from (e.g., are each completely outside of) a horizontal area of the staircase region 106 of the microelectronic device structure 100.

The microelectronic device structure 100 further includes at least one string driver 108 connected to a voltage source. An individual string driver 108 is configured to provide voltages for various operations (e.g., reading, writing, erasing) carried out on a group of memory cells of a block 111 of the plane 102 of the microelectronic device structure 100. The microelectronic device structure 100 further includes a first source controller 110a operatively associated with the first source structure 126a within first memory cell region 104a, and a second source controller 110b operatively associated with the second source structure 126b within the second memory cell region 104b. The first source controller 110a and the second source controller 110b may control voltage to the first source structure 126a and the second source structure 126b, respectively, by controlling access to a ground signal or a predetermined voltage different from a ground signal.

For example, a random read operation may be performed to read information stored in a group of memory cells 112 (e.g., an 8 KB group) within the second memory cell region 104b. An individual string driver 108 connected to a voltage source may direct a voltage to an individual word line of the block 111, while the second source controller 110b effectuates an ON state of (e.g., directs a ground (GND) signal to) the second source structure 126b and the first source controller 110a effectuates an OFF state of (e.g., blocks the GND signal to) the first source structure 126a. As a result, since the first source structure 126a and the second source structure 126b are separated (e.g., physically separated, electrically separated) in the staircase region 106, the total capacitive load during the random read operation may be reduced because string driver 108 only boosts one-half (50 percent) of the cell pillars operatively associated therewith (e.g., only the cell pillars within the second memory cell region 104b, rather than the cell pillars within both the second memory cell region 104b and the first memory cell region 104 a). This essentially reduces the capacitive load by 50 percent as compared to where cell pillars within both the second memory cell region 104b and the first memory cell region 104a are boosted during a read operation. The decrease in capacitive load provides for faster random read times with decreased latency.

In FIG. 1, the microelectronic device structure 100 may comprise a 3D-NAND Flash memory device structure with blocks 111 respectively having a CBSC within a horizontal area thereof. In this example, the string driver 108 may be a 16 KB word line driver configured to drive a voltage in across the entire plane 102 (e.g., in both the first memory cell region 104a and the second memory cell region 104b). However, this is merely exemplary and is not intended to be limiting in any way. In this example, the separated first source structure 126a and second source structure 126 b facilitate random read operations of 8 KB by controlling GND signal to the first memory cell region 104a and the second memory cell region 104b via the first source controller 110a and the second source controller 110b, respectively. As explained above, this configuration may reduce latency and save energy.

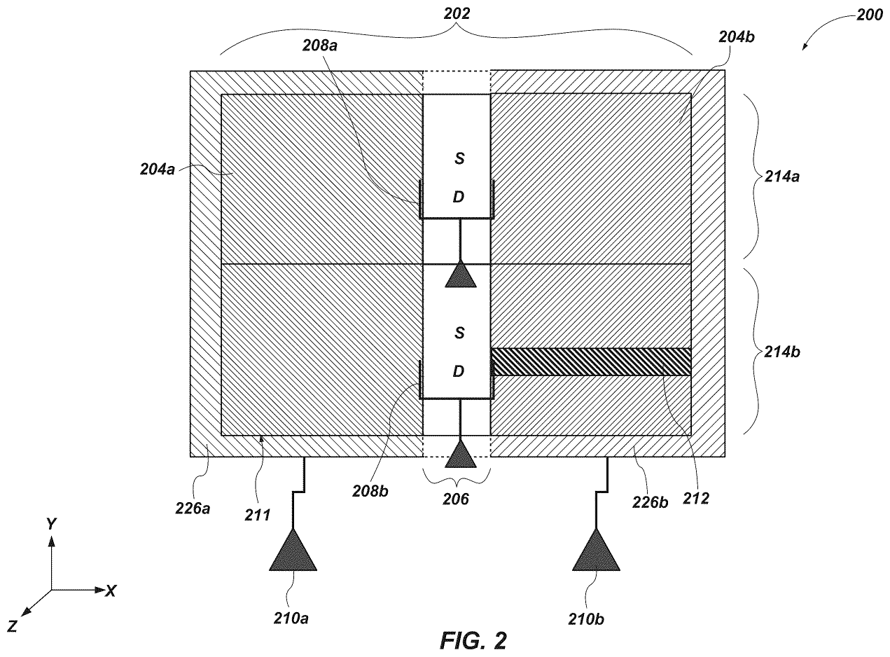

FIG. 2 illustrates a schematic of a microelectronic device structure 200, according to an additional embodiment of the disclosure. To avoid repetition, not all features (e.g., structures, materials, regions, devices) shown in FIG. 2 are described in detail herein. Rather, unless described otherwise below, in FIG. 2, a feature designated by a reference numeral that is a 100 increment of the reference numeral of a feature previously described with reference to FIG. 1 will be understood to be substantially similar to the previously described feature. By way of non-limiting example, unless described otherwise below, features designated by the reference numerals 202, 206 in FIG. 2 will be understood to respectively be substantially similar to the plane 102 and staircase region 106 previously described herein with reference to FIG. 1.

The microelectronic device structure 200 includes a plane 202. The plane 202 may extend horizontally in a first direction (e.g., Y-direction) and includes a number of blocks 211 of memory arrays. In this example, the microelectronic device structure 200 may have a first memory cell region 204a and a second memory cell region 204b separated by a staircase region 206. Individual blocks 111 of the microelectronic device structure 200 may have a CBSC horizontally overlapping (e.g., in the X-direction) the staircase region 206 of the microelectronic device structure 200. The CBSC is horizontally located, in the X-direction, in the center or between two memory cell sections of the block 211 that respectively horizontally overlap one of the first memory cell region 104a and the second memory cell region 104b of the microelectronic device structure 100.

The microelectronic device structure 200 may further include a first source structure 226a within a horizontal area of first memory cell region 204a, and a second source structure 226b within a horizontal area of the second memory cell region 204b. In this example, the first source structure 226a is electrically separated from the second source structure 226b. Similar to the embodiment previously described with reference to FIG. 1, as compared to conventional source structures that would extend continuously throughout the plane 202, a source structure is not provided within at least a portion of the staircase region 206, effectively splitting (e.g., physically separating, electrically separating) the first source structure 226a from the second source structure 226b. In this example, the first source structure 226a and the second source structure 226b are both entirely absent from (e.g., are each completely outside of) a horizontal area of the staircase region 206 of the microelectronic device structure 200.

In this example, the microelectronic device structure 200 may be configured such that the plane 202 has a so-called “folded” configuration including a top semi-plane 214a and a bottom semi-pane 214b. The top semi-plane 214a and the bottom semi-pane 214b may have different string drivers 208 operatively associated therewith; for example, a first string driver 208 a associated with a word line within the top semi-plane 214a, and a second string driver 208 b associated with a word line within the bottom semi-pane 214b. When a group of memory cells 212 (e.g., a 4 KB group) within the bottom semi-pane 214b of the second source structure 226b is to be read in a random read operation, the second string driver 208b may direct a voltage (e.g., a transistor of the second string driver 208b may be in an ON state) to an individual word line operatively associated with the group of memory cells 212 (e.g., a 4 KB group) while the first string driver 208a does not direct a voltage (e.g., a transistor of the first string driver 208a may be in an OFF state) to a different, individual word line operatively associated therewith. In addition, the second source controller 110b may effectuate an ON state of (e.g., directs a GND signal to) the second source structure 126b, and the first source controller 110a may effectuate an OFF state of (e.g., blocks the GND signal to) the first source structure 126a. As a result, since the first source structure 126a and the second source structure 126b are separated (e.g., physically separated, electrically separated) in the staircase region 106, the total capacitive load during the random read operation may be reduced because the second string driver 108b only boosts one-half (50 percent) of the cell pillars operatively associated therewith (e.g., only the cell pillars within a horizontal area corresponding to the overlap of the bottom semi-pane 214b and the second memory cell region 104 b, rather than the cell pillars within a larger horizontal area corresponding to the overlap of the bottom semi-pane 214b and both of the second memory cell region 104 b and the first memory cell region 104 a). This essentially reduces the capacitive load by 50 percent as compared to where cell pillars within both the second memory cell region 104b and the first memory cell region 104a are boosted during a read operation, effectuating faster read times, decreased latencies, and energy savings.

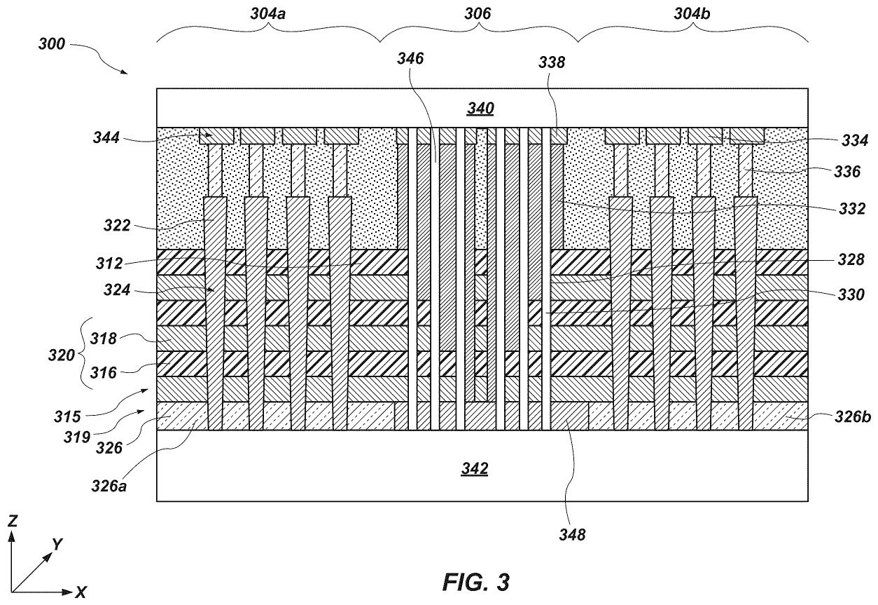

FIG. 3 shows simplified, partial vertical cross-sectional view of a microelectronic device structure 300, according to one embodiment of the disclosure. To avoid repetition, not all features (e.g., structures, materials, regions, devices) shown in FIG. 3 are described in detail herein. Rather, unless described otherwise below, in FIG. 3, a feature designated by a reference numeral that is a 100 increment of the reference numeral of a feature previously described with reference to one or more of FIG. 1 and FIG. 2 will be understood to be substantially similar to the previously described feature. By way of non-limiting example, unless described otherwise below, features designated by the reference numerals 304a, 306 in FIG. 3 will be understood to respectively be substantially similar to the first memory cell region 104a and the staircase region 106 previously described herein with reference to FIG. 1.

The microelectronic device structure 300 may include a stack structure 315 vertically overlying a control logic structure 342. The stack structure 315 may include tiers 320 vertically stacked relative to one another and respectively including conductive material 316 and insulative material 318 vertically neighboring the conductive material 316. Cell pillar structures 322 may vertically extend (e.g., in the Z-direction) through the stack structure 315 and to, into, or through one source tier 319 vertically interposed between the stack structure 315 and the control logic structure 342. Digit line structures 334 and conductive routing structures 338 vertically overlie the stack structure 315. The cell pillar structures 322 may respectively include semiconductor material coupled to one or more of the digit line structure 334 and split source structure 326 within the source tier 319. Digit line contact structures 336 vertically extend between and couple the cell pillar structures 322 to the digit line structures 334. In addition, conductive contact structures 332 may vertically extend between and couple some of the conductive routing structures 338 and the conductive material 316 of at least some of the tiers 320 of the stack structure 315. The microelectronic device structure 300 may also include an interconnect region 340 disposed above (e.g., in the Z-direction) the digit line contact structures 336.

Still referring to FIG. 3, the split source structures 326 of the source tier 319 may individually be formed of and include conductive material and may include a first source structure 326a within a horizontal area of the first memory cell region 304a, and a second source structure 326b within a horizontal area of the first memory cell region 304a. The staircase region 306 may be free of any of the split source structures 326 within a horizontal area thereof. The first source structure 326a may be substantially confined within the horizontal area of the first memory cell region 304a; and the second source structure 326b may be substantially confined within the horizontal area of the second memory cell region 304b. A dielectric material 348 positioned within the horizontal area of the staircase region 306 may vertically overlap (e.g., in the Z-direction) and horizontally intervene (e.g., in the X-direction) between the first source structure 326a and the second source structure 326b. The dielectric material 348 may electrically isolate the first source structure 326a and the second source structure 326b.

Still referring to FIG. 3, the tiers 320 of the stack structure 315 may individually include at least one level of the conductive material 316 vertically neighboring at least one level of the insulative material 318. The stack structure 315 may be formed to include any desired number of the tiers 320, such as greater than or equal to sixteen (16) of the tiers 320, greater than or equal to thirty-two (32) of the tiers 320, greater than or equal to sixty-four (64) of the tiers 320, greater than or equal to one hundred twenty-eight (128) of the tiers 320, or greater than or equal to two hundred fifty-six (256) of the tiers 320.

The conductive material 316 of some of the tiers 320 (e.g., relatively lower tiers 320) may be employed as select lines for select gates (e.g., source side select gates (SGSs)) of the stack structure 315. In some embodiments, a level of conductive material 316 of a vertically lowermost one of the tiers 320 of the stack structure 315 is employed as a lower select line for lower select gates (e.g., SGSs) of the stack structure 315. In addition, the conductive material 316 of some others of the tiers 320 (e.g., relatively higher tiers 320) may be employed as select lines for upper select gate(s) (e.g., drain side select gate(s) (SGDs)) of the stack structure 315. In some embodiments, horizontally neighboring (e.g., in the Y-direction) portions of a level of conductive material 316 of a vertically uppermost one of the tiers 320 of the stack structure 315 are employed as select lines for upper select gates (e.g., SGDs) of the stack structure 315. In addition, conductive material 316 of yet some others of the tiers 320 may be employed as local word lines (LWLs) for control gates of access devices of memory cells 324 (e.g., non-volatile memory cells, such as charge-trapping memory cells or floating gate memory cells) located at intersections of the cell pillar structures 322 and the conductive material 316 of the yet some others of the tiers 320.

With continued reference to FIG. 3, the stack structure 315 may further include at least one staircase structure 328 horizontally positioned within the staircase region 306. The staircase structure 328 may include steps 330 partially defined by horizontal end(s) (e.g., in the X-direction) of at least some of the tiers 320 of the stack structure 315. In this example, the staircase structure 328 is horizontally positioned between a portion of the stack structure 315 within the first memory cell region 304a and an additional portion of the stack structure 315 within the second memory cell region 304b. The steps 330 of the staircase structure 328 may be employed as contact regions to electrically connect the conductive material 316 of at least some of the tiers 320 of the stack structure 315 to other features (e.g., structures, materials, devices) of the microelectronic device structure 300. A quantity of steps 330 in the staircase structure 328 may be substantially the same as (e.g., equal to) or may be different than (e.g., less than, greater than) the quantity of tiers 320 in the stack structure 315 of each of the first memory cell region 304a and the second memory cell region 304b. As shown in FIG. 3, in some embodiments, the steps 330 of the staircase structure 328 are arranged in order, such that steps 330 directly horizontally adjacent one another in the X-direction correspond to tiers 320 of the stack structure 315 directly vertically adjacent (e.g., in the Z-direction) one another. In additional embodiments, the steps 330 of the staircase structure 328 are arranged out of order, such that at least some steps 330 of the staircase structure 328 directly horizontally adjacent one another in the X-direction correspond to tiers 320 of stack structure 315 not directly vertically adjacent (e.g., in the Z-direction) one another.

At least some of the conductive contact structures 332 may contact (e.g., electrically contact, physically contact) at least some (e.g., each) of the steps 330 of the staircase structure 328 of the stack structure 315 to provide electrical access to the conductive material 316 of at least some of the tiers 320 of the stack structure 315. At least some of the conductive contact structures 332 may be coupled to the conductive material 316 of at least some of the tiers 320 of the stack structure 315 at the steps 330 of the staircase structure 328. As shown in FIG. 3, at least some of the conductive contact structures 332 may physically contact and upwardly vertically extend (e.g., in the Z-direction) from the conductive material 316 of at least some of the tiers 320 of the stack structure 315 at the steps 330 of the staircase structure 328. The staircase structure 328 of the stack structure 315 may include at least one conductive contact structure 332 physically contacting each step 330 thereof; or the staircase structure 328 of the stack structure 315 may be free of at least one conductive contact structure 332 physically contacting at least one step 330 thereof.

Still referring to FIG. 3, the cell pillar structures 322 may each individually be formed of and include a stack of materials. By way of non-limiting example, each of the cell pillar structures 322 may be formed to include a charge-blocking material, such as first dielectric oxide material (e.g., SiOₓ, such as SiO₂; AlOₓ, such as Al₂O₃); a charge-trapping material, such as a dielectric nitride material (e.g., SiN_{y}, such as Si₃N₄); a tunnel dielectric material, such as a second oxide dielectric material (e.g., SiOₓ, such as SiO₂); a channel material, such as a semiconductive material (e.g., silicon, such as polycrystalline Si); and a dielectric fill material (e.g., a dielectric oxide, a dielectric nitride, air). The charge-blocking material may be formed on or over surfaces of the conductive material 316 and the insulative material 318 of the tiers 320 of stack structure 315 at least partially defining horizontal boundaries of the cell pillar structures 322; the charge-trapping material may be horizontally surrounded by the charge-blocking material; the tunnel dielectric material may be horizontally surrounded by the charge-trapping material; the channel material may be horizontally surrounded by the tunnel dielectric material; and the dielectric fill material may be horizontally surrounded by the channel material.

With continued reference to FIG. 3, intersections of the cell pillar structures 322 and the conductive material 316 of the tiers 320 of the stack structure 315 may define vertically extending strings of memory cells 324 coupled in series with one another within the stack structure 315. In some embodiments, the memory cells 324 formed at the intersections of the conductive material 316 and the cell pillar structures 322 within different tiers 320 of the stack structure 315 comprise so-called “MONOS” (metal-oxide-nitride-oxide-semiconductor) memory cells. In additional embodiments, the memory cells 324 comprise so-called “TANOS” (tantalum nitride-aluminum-oxide-nitride-oxide-semiconductor) memory cells, or so-called “BETANOS” (band/barrier engineered TANOS) memory cells, each of which are subsets of MONOS memory cells. In further embodiments, the memory cells 324 comprise so-called “floating gate” memory cells including floating gates (e.g., metallic floating gates) as charge storage structures. The floating gates may horizontally intervene between central structures of the cell pillar structures 322 and the conductive material 316 of the different tiers 320 of the stack structure 315. As shown in FIG. 3, the cell pillar structures 322 (and, hence, the vertically extending strings of the memory cells 324) may individually be coupled to one of the split source structures 326 (e.g., the first source structure 326a within the first memory cell region 304a; or the second source structure 326b within the second memory cell region 304b) of the source tier 319.

Within a conductive routing tier 344 overlying the stack structure 315, the digit line structures 334 and conductive routing structures 338 may be formed to horizontally extend (e.g., in the X-direction, in the Y-direction) in desirable paths. While FIG. 3 depicts the microelectronic device structure 300 as being formed to include single (e.g., only) one conductive routing tier 344 formed over the stack structure 315, multiple (e.g., more than one) conductive routing tiers 344 may be formed over the stack structure 315. By way of non-limiting example, two or more (e.g., three or more) conductive routing tiers 344 may be formed over the stack structure 315. In such embodiments, the different conductive routing tiers 344 may have different configurations (e.g., different features, different feature configurations, different feature arrangements) than one another that together facilitate desirable conductive paths within the microelectronic device structure 300. At least some of the features (e.g., at least some conductive routing structures) of at least one of the different conductive routing tiers 344 may be electrically connected (e.g., by way of one or more vertically intervening conductive contact structures) to at least some of the features (e.g., at least some conductive routing structures) of at least one other of the different conductive routing tiers 344.

Within an individual conductive routing tier 344 the digit line structures 334 and the conductive routing structures 338 may be located at substantially the same vertical position (e.g., elevation in the Z-direction) as one another within the microelectronic device structure 300. In addition, the digit line structures 334 and the conductive routing structures 338 may have substantially the same thickness (e.g., height in the Z-direction) as one another, or may have different thicknesses than one another. Moreover, the digit line structures 334 and the conductive routing structures 338 may have substantially the same material composition as one another, or may have different material compositions than one another. In some embodiments, the digit line structures 334 and the conductive routing structures 338 have substantially the same thickness as one another, and have substantially the same material composition as one another. The digit line structures 334 and the conductive routing structures 338 may, for example, be formed (e.g., simultaneously formed, sequentially formed) form patterning a common conductive material.

As shown in FIG. 3, the digit line structures 334 may be formed vertically over and in electrical communication with the cell pillar structures 322 (and, hence, the vertically extending strings of memory cells 324). The digit line structures 334 may respectively be formed of and include conductive material, and may exhibit horizontally elongate shapes extending in parallel in a first horizontal direction (e.g., the Y-direction). As used herein, the term “parallel” means substantially parallel. The digit line structures 334 may each exhibit substantially the same dimensions (e.g., width in the X-direction, length in a Y-direction, height in the Z-direction), shape, and spacing (e.g., in the X-direction). In additional embodiments, one or more of the digit line structures 334 may exhibit one or more of at least one different dimension (e.g., a different length, a different width, a different height) and a different shape than one or more other of the digit line structures 334, and/or the spacing (e.g., in the X-direction) between at least two horizontally neighboring digit line structures 334 may be different than the spacing between at least two other horizontally neighboring digit line structures 334.

The conductive routing structures 338 may be formed vertically over and in electrical communication with additional features (e.g., structures, materials, devices) of the microelectronic device structure 300. For example, as shown in FIG. 3, at least some of the conductive routing structures 338 may contact (e.g., electrically contact, physically contact) the conductive contact structures 332 of the microelectronic device structure 300. Some of the conductive routing structures 338 may horizontally extend between and electrically connect at least some of the conductive contact structures 332 to other features of the microelectronic device structure 300 (e.g., structures, materials, devices).

As shown in FIG. 3, the digit line contact structures 336 may be formed to contact (e.g., electrically contact, physically contact) and vertically extend between the cell pillar structures 322 and the digit line structures 334. The digit line contact structures 336 may each individually be formed of and include conductive material. By way of non-limiting example, the digit line contact structures 336 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the digit line contact structures 336 are formed of and include W.

The microelectronic device structure 300 may further comprise floating support structures 346 within the staircase region 306 thereof. The floating support structures 346 may extend vertically (e.g., Z-direction) through the stack structure 315, and may be horizontally positioned (e.g., in the X-direction) between horizontally neighboring conductive contact structures 332. The floating support structures 346 may individually vertically extend completely through each of the stack structure 315 and the source tier 319. As shown in FIG. 3, in some embodiments, the floating support structures 346 respectively vertically extend through each of the conductive routing tier 344, the stack structure 315, and the source tier 319. In some embodiments, the floating support structures 346 horizontally alternate with the conductive contact structures 332 in the X-direction.

The floating support structures 346 may serve as support structures during and/or after formation of one or more components of the microelectronic device structure 300. For example, the floating support structures 346 may serve as support structures for the formation of the conductive material 316 of the tiers 320 of the stack structure 315 through so-called “replacement gate” processing. The floating support structures 346 may be electrically isolated from the split source structures 326 by way of the dielectric material 348.

The microelectronic device structure 300, including the split source structures 326 of the source tier 319, may be formed in a variety of ways. In some examples, the split source structures 326 are formed prior to formation of the stack structure 315. For example, an array wafer including the split source structures 326, the stack structure 315, the cell pillar structures 322, the staircase structure 328, and the digit line structures 334 (without limitation) may be formed, and the array wafer may be bonded (e.g., dielectric-to-dielectric bonded) to a separately formed control circuitry wafer including the control logic structure 342 to form the microelectronic device structure 300. Under such a process, the split source structures 326 may be more vertically proximate to the control logic structure 342 than are the digit line structures 334. In additional embodiments, the split source structures 326 are formed after bonding an array wafer including the stack structure 315, the cell pillar structures 322, the staircase structure 328, and the digit line structures 334 to a separately formed control circuitry wafer including the control logic structure 342. Under such a process, also referred to herein as a so-called “source last” process, the split source structures 326 may be more vertically distill from to the control logic structure 342 than are the digit line structures 334.

In some embodiments, the microelectronic device structure 300 may not include a staircase structure 328 in the staircase region 306. Instead, within the staircase region 306, equivalents to the conductive contact structures 332 may be formed to vertically extend to contact the conductive material 316 of at least some of the tiers 320 in the absence of the staircase structure 328. In such embodiments, the conductive material 316 of the tiers 320 may be segmented (e.g., discontinuous) within the staircase region 306 (e.g., by way of at least one dielectric structure extending completely though the stack structure 315); or at least a portion of the conductive material 316 of respective ones of the tiers 320 may horizontally extend (e.g., in the X-direction) continuously through the staircase region 306.

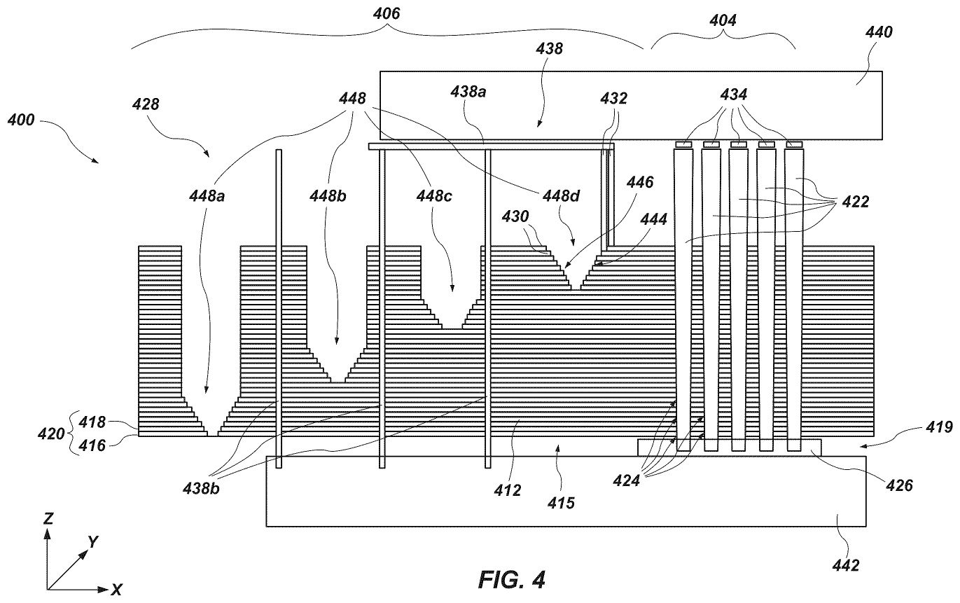

FIG. 4 shows an example of a microelectronic device structure 400, according to one example of the disclosure. To avoid repetition, not all features (e.g., structures, materials, regions, devices) shown in FIG. 4 are described in detail herein. Rather, unless described otherwise below, in FIG. 4, a feature designated by a reference numeral that is a 100 increment of the reference numeral of a feature previously described with reference to one or more of FIGS. 1 through 3 will be understood to be substantially similar to the previously described feature. By way of non-limiting example, unless described otherwise below, features designated by the reference numerals 422, 406 in FIG. 4, respectively, will be understood to be substantially similar to the cell pillar structures 322 and the staircase region 306 previously described herein with reference to FIG. 3.

In the examples described above, the staircase region (e.g., staircase regions 106, 206, 306) has been described in the context of a CBSC structure. However, a source structure may also be removed from a staircase region in other examples of microelectronic device structures to reduce latencies and provide energy savings. Referring to FIG. 4, the microelectronic device structure 400 includes a stack structure 415 including a vertically alternating (e.g., in the Z-direction) sequence of levels of conductive material 416 (e.g., access line plates, word line plates) and levels of insulative material 418 arranged in tiers 420. In addition, as shown in FIG. 4, the stack structure 415 includes a memory cell region 404 and a staircase region 406 horizontally neighboring (e.g., in the X-direction) a first horizontal boundary of the memory cell region 404. As described in further detail below, the microelectronic device structure 400 further includes additional components (e.g., features, structures, devices) within boundaries of the different horizontal regions (e.g., the memory cell region 404 and the staircase region 406) of the stack structure 415.

Each of the tiers 420 of the stack structure 415 of the microelectronic device structure 400 may include one (1) level of the conductive material 416 vertically neighboring one level of the insulative material 418. The stack structure 415 may include a desired quantity of the tiers 420. As shown in FIG. 4, in some embodiments, the stack structure 415 includes thirty-two (32) of the tiers 420. In additional embodiments, the stack structure 415 includes a different number of the tiers 420, such as less than thirty-two (32) of the tiers 420 (e.g., less than or equal to thirty (30) of the tiers 420, less than or equal to twenty (20) of the tiers 420, less than or equal to ten (10) of the tiers 420); or greater than thirty-two (32) of the tiers 420 (e.g., greater than or equal to fifty (50) of the tiers 420, greater than or equal to one hundred (100) of the tiers 420).

Within horizontal boundaries (e.g., in the X-direction) of the memory cell region 404 of the stack structure 415, the microelectronic device structure 400 may include vertically extending cell pillar structures 422, a source structure 426, and digit line structures 434 (e.g., digit lines, data lines, bit lines). The source structure 426 may be disposed on or over a source tier 419 and may be vertically interposed between the stack structure 415 and a control logic structure 442 including control logic circuitry. The digit line structures 434 may vertically overlie the stack structure 415. The cell pillar structures 422 vertically extend from the digit line structures 434, through the stack structure 415, and to the source structure 426 of the source tier 419.

Each of the cell pillar structures 422 may include a semiconductive pillar (e.g., a polysilicon pillar, a silicon-germanium pillar) at least partially surrounded by one or more charge storage structures (e.g., a charge trapping structure, such as a charge trapping structure comprising an oxide-nitride-oxide (“ONO”) material; floating gate structures). Intersections of portions of cell pillar structures 422 and the conductive material 416 of some of the tiers 420 of the stack structure 415 may define vertically extending strings of memory cells 424 coupled in series with one another within the memory cell region 404 of the stack structure 415.

The source structure 426 of the source tier 319 underlies a lowermost tier 420 of the stack structure 415. As shown in FIG. 4, at least a portion of the source structure 426 may be positioned within a horizontal area of the memory cell region 404 of the stack structure 415. In some embodiments, the source structure 426 is substantially confined within the horizontal area of the memory cell region 404. The horizontal area of the staircase region 406 of the stack structure 415 may be substantially free of any portions of the source structure 426.

With continued reference to FIG. 4, within a horizontal area of the staircase region 406 of the stack structure 415, the microelectronic device structure 300 may include stadium structures 448 distributed within the stack structure 415 and individually including steps 430 (e.g., contact regions) defined by horizontal ends of some of the tiers 420. In addition, the microelectronic device structure 400 may further include conductive contact structures 432 (e.g., access line contacts, word line contacts) contacting (e.g., physically contacting, electrically contacting) the steps 430 of the stadium structures 448 to provide electrical access to the levels of conductive material 416 of the stack structure 415; and conductive routing structures 438 (e.g., access line routing structures, word line routing structures) extending from and between the conductive contact structures 432 and control logic circuitry of the control logic structure 442.

As shown in FIG. 4, the staircase region 406 of the stack structure 415 may include multiple (e.g., more than one) stadium structures 448 positioned at different vertical elevations (e.g., in the Z-direction) than one another within the stack structure 415. For example, the staircase region 406 of the stack structure 415 may include a first stadium structure 448a, a second stadium structure 448b at a relatively lower vertical position (e.g., in the Z-direction) within the stack structure 415 than the first stadium structure 448a, a third stadium structure 448c at a relatively lower vertical position within the stack structure 415 than the second stadium structure 448b, and a fourth stadium structure 448d at a relatively lower vertical position within the stack structure 415 than the third stadium structure 448c. The different vertical positions of the different stadium structures 448 (e.g., the first stadium structure 448a, the second stadium structure 448b, the third stadium structure 448c, the fourth stadium structure 448d) permits electrical connections between the conductive material 416 of the tiers 420 at the different vertical positions of the different stadium structures 448 and other components of the microelectronic device structure 400.

The staircase region 406 of the stack structure 415 may include any desired quantity and distribution (e.g., spacing and arrangement) of the stadium structures 448. As shown in FIG. 4, in some embodiments, the staircase region 406 of the stack structure 415 includes four (4) of the stadium structures 448; the stadium structures 448 are substantially uniformly (e.g., equally, evenly) spaced; and vertical positions (e.g., in the Z-direction) of the stadium structures 448 within the stack structure 415 become deeper (e.g., vertically farther from a uppermost surface of the stack structure 415, vertically closer to the lowermost surface of the stack structure 415) in a direction (e.g., the X-direction) horizontally-extending away from the memory cell region 404 (and, hence, the vertically-extending cell pillar structures 422 thereof) of the stack structure 415. In additional embodiments, the staircase region 406 of the stack structure 415 may include a different quantity of the stadium structures 448 and/or a different distribution of the stadium structures 448 than that depicted in FIG. 4. For example, the staircase region 406 of the stack structure 415 may include more than four (4) of the stadium structures 448 (e.g., greater than or equal to five (5) of the stadium structures 448, greater than or equal to ten (10) of the stadium structures 448, greater than or equal to twenty-five (25) of the stadium structures 448, greater than or equal to fifty (50) of the stadium structures 448), or less than four (4) of the stadium structures 448 (e.g., less than or equal to three (3) of the stadium structures 448, less than or equal to two (2) of the stadium structures 448, only one (1) of the stadium structures 448). As another example, the stadium structures 448 may be at least partially non-uniformly (e.g., non-equally, non-evenly) spaced, such that at least one of the stadium structures 448 is separated from at least two other of the stadium structures 448 laterally-neighboring (e.g., in the X-direction) the at least one stadium structure 448 by different (e.g., non-equal) distances. As an additional non-limiting example, vertical positions (e.g., in the Z-direction) of the stadium structures 448 within the stack structure 415 may become shallower (e.g., vertically closer to a uppermost surface of the stack structure 415, vertically farther from the lowermost surface of the stack structure 415) in a direction (e.g., the X-direction) horizontally-extending away from the memory cell region 404 of the stack structure 415, or may vary in another manner (e.g., may alternate between relatively deeper and relatively shallower vertical positions, may alternate between relatively shallower and relatively deeper vertical positions) in a direction horizontally-extending away from the memory cell region 404 of the stack structure 415.

As shown in FIG. 4, each of the stadium structures 448 may individually include a forward staircase structure 444 and a reverse staircase structure 446 that mirrors the forward staircase structure 444. A phantom line extending from a top of the forward staircase structure 444 to a bottom of the forward staircase structure 444 may have a positive slope, and another phantom line extending from a top of the reverse staircase structure 446 to a bottom of the reverse staircase structure 446 may have a negative slope. The forward staircase structure 444 and the reverse staircase structure 446 of each of the stadium structures 448 may serve as redundant and/or alternative means of connecting to one or more of the tiers 420 of the stack structure 415. In additional embodiments, the staircase region 406 of the stack structure 415 may exhibit different configuration one or more of the stadium structures 448. As a non-limiting example, one or more (e.g., each) of the stadium structures 448 may be modified to include a forward staircase structure 444 but not a reverse staircase structure 446 (e.g., the reverse staircase structure 446 may be absent). As another non-limiting example, one or more (e.g., each) of the stadium structures 448 may be modified to include a reverse staircase structure 446 but not a forward staircase structure 444 (e.g., the forward staircase structure 444 may be absent). As a further non-limiting example, one or more (e.g., each) of the stadium structures 448 may be modified such that the reverse staircase structure 446 thereof is at least partially vertically offset from the forward staircase structure 444 thereof.

Each of the stadium structures 448 within the staircase region 406 of the stack structure 415 may individually include a desired quantity of steps 430. Each of the stadium structures 448 may include substantially the same quantity of steps 430 as each other of the stadium structures 448, or at least one of the stadium structures 448 may include a different quantity of steps 430 than at least one other of the stadium structures 448. In some embodiments, at least one of the stadium structures 448 includes a different (e.g., greater, lower) quantity of steps 430 than at least one other of the stadium structures 448.

As shown in FIG. 4, in some embodiments, the steps 430 of each of the stadium structures 448 are arranged in order, such that steps 430 directly horizontally adjacent (e.g., in the X-direction) one another correspond to tiers 420 of the stack structure 415 directly vertically adjacent (e.g., in the Z-direction) one another. In additional embodiments, the steps 430 of one or more of the stadium structures 448 are arranged out of order, such that at least some steps 430 of the stadium structures 448 directly horizontally adjacent (e.g., in the X-direction) one another correspond to tiers 420 of stack structure 415 not directly vertically adjacent (e.g., in the Z-direction) one another.

The conductive contact structures 432 may be coupled to the conductive material 416 of the tiers 420 at the steps 430 of the stadium structures 448, and may respectively electrically couple the conductive material 416 of an individual tier 420 to some of the conductive routing structures 438 of the microelectronic device structure 400. Each of tiers 420 of the stack structure 415 may be coupled to at least one of the conductive contact structures 432 at one or more of the steps 430 of one or more of the stadium structures 448. For each of the stadium structures 448 (e.g., the first stadium structure 448a, the second stadium structure 448b, the third stadium structure 448c, the fourth stadium structure 448d), the conductive contact structures 432 may be formed on or over a single (e.g., only one) staircase structure thereof (e.g., the forward staircase structure 444 thereof, or the reverse staircase structure 446 thereof), or may be formed on or over multiple (e.g., more than one) of the staircase structures thereof (e.g., the forward staircase structure 444 thereof and the reverse staircase structure 446 thereof). As non-limiting example, for one or more of the stadium structures 448, each of the steps 430 of the forward staircase structure 444 thereof may have a conductive contact structure 432 thereon or thereover. As another non-limiting example, for one or more of the stadium structures 448, each of the steps 430 of the reverse staircase structure 446 thereof may have a conductive contact structure 432 thereon or thereover. As a further non-limiting example, for one or more of the stadium structures 448, at least a portion (e.g., less than or equal to all) the steps 430 of the forward staircase structure 444 thereof may each have a conductive contact structure 432 thereon or thereover, and at least a portion (e.g., less than or equal to all) the steps 430 of the reverse staircase structure 446 thereof may each have a conductive contact structure 432 thereon or thereover. In addition, conductive contact structures 332 formed on or over the same staircase structure (e.g., the forward staircase structure 444 or the reverse staircase structure 446) of the same stadium structure 448 (e.g., the first stadium structure 448a, the second stadium structure 448b, the third stadium structure 448c, or the fourth stadium structure 448d) may be substantially horizontally-aligned with one another (e.g., in the Y-direction shown in FIG. 4), or may be at least partially non-aligned (e.g., offset) with one another (e.g., in the Y-direction shown in FIG. 4). As shown in FIG. 4, in some embodiments, conductive contact structures 432 formed on or over the same staircase structure (e.g., the forward staircase structure 444) of the same stadium structure 448 (e.g., the fourth stadium structure 448d) are horizontally-offset from one another in the Y-direction.

With continued reference to FIG. 4, the conductive routing structures 438 may electrically connect the conductive contact structures 432 and the control logic circuitry of the control logic structure 442. The conductive routing structures 438 may, for example, extend from the conductive contact structures 432, through the staircase region 406 of the stack structure 415 and to or into the control logic structure 442. As shown in FIG. 4, the conductive routing structures 438 may include horizontally extending regions 438a and vertically extending regions 438b. At least some of the horizontally extending regions 438a of the conductive routing structures 438 may horizontally extend (e.g., in one or more of the X-direction and the Y-direction) from the conductive contact structures 432 to the vertically extending regions 438b of the conductive routing structures 438. In addition, at least some of the vertically extending regions 438b of the conductive routing structures 438 may vertically extend (e.g., in the Z-direction) from the horizontally extending regions 438a toward (e.g., to) the control logic structure 442. Thus, the conductive routing structures 438 may form an electrical connection between control logic circuitry of the control logic structure 442 and the conductive material 416 of the different tiers 420 of the stack structure 415 to provide electrical access to the conductive material 416 (e.g., for reading, writing, or erasing data associated with the memory cells 424 within the memory cell region 404 of the stack structure 415). As mentioned above, the vertically extending regions 438b do not horizontally overlap the horizontal area of the source structure 426 of the source tier 419 since source structure 426 is entirely absent from the horizontal area of the staircase region 406 of the microelectronic device structure 400.

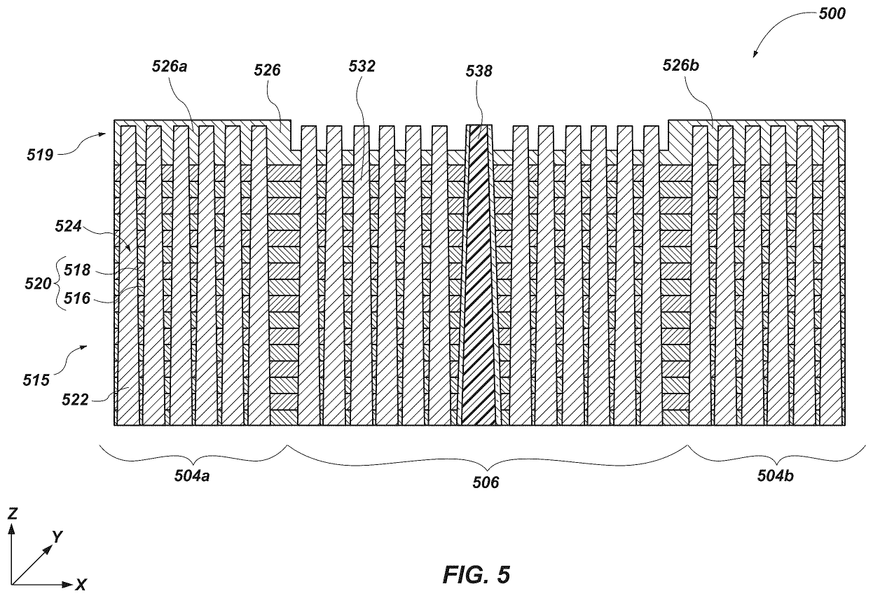

FIG. 5 shows an example of a microelectronic device structure 500, according to one embodiment of the disclosure. To avoid repetition, not all features (e.g., structures, materials, regions, devices) shown in FIG. 5 are described in detail herein. Rather, unless described otherwise below, in FIG. 5, a feature designated by a reference numeral that is a 100 increment of the reference numeral of a feature previously described with reference to one or more of FIGS. 1 through 4 will be understood to be substantially similar to the previously described feature. By way of non-limiting example, unless described otherwise below, features designated by the reference numerals 520, 522 in FIG. 5 respectively will be understood to be substantially similar to the tiers 420 and the cell pillar structures 422 previously described herein with reference to FIG. 4.

Referring to FIG. 5, the microelectronic device structure 500 may be formed to include a first memory cell region 504a, a second memory cell region 504b, and a staircase region 506 interposed therebetween. The microelectronic device structure 500 includes a stack structure 515 including levels of conductive material 516 and levels of insulative material 518 arranged in tiers 520. The microelectronic device structure 500 further comprises cell pillar structures 522 vertically extending (e.g., in the Z-direction) through the tiers 520 of the stack structure 515. Intersections between the conductive material 516 of some of the tiers 520 and portions of the cell pillar structures 522 define memory cells 524 (e.g., non-volatile memory cells, such as charge-trapping memory cells) of the microelectronic device structure 500.

The microelectronic device structure 500 further comprises multiple source structures 526 (e.g., two source structures 526) vertically neighboring (e.g., vertically overlying) the stack structure 515 (e.g., neighboring in the Z-direction). For example, the source structures 526 may include a first source structure 526a at least partially within a horizontal area of the first memory cell region 504a, and a second source structure 526b vertically overlapping the first source structure 526a and at least partially within a horizontal area of the second memory cell region 504b. In some embodiments, at least a portion (e.g., substantially all) of the source structure 526 is formed after the formation of the stack structure 515 and the cell pillar structures 522 through so-called “source-last” processing. For example, following the formation of the stack structure 515 and the cell pillar structures 522, the stack structure 515 may be vertically inverted (e.g., flipped upside down), a preliminary substrate may be at least partially removed, and then the source structure 526 may be formed to contact portions of the cell pillar structures 522. In additional embodiments, at least a portion of the source structure 526 is formed before the formation of the stack structure 515 and the cell pillar structures 522 through so-called “source-first” processing. For example, a source material may be formed on or over a preliminary substrate, the stack structure 515 and the cell pillar structures 522 may be formed over the source material, the resulting assembly may be vertically inverted (e.g., flipped upside down), and then portions of the preliminary substrate and the source material may be removed to form the source structure 526.

As shown in FIG. 5, the source structures 526 (e.g., the first source structure 526a, the second source structure 526b) may respectively at least partially (e.g., completely) absent from the horizontal area of the staircase region 506 of the stack structure 515. In some embodiments, a horizontal area of the staircase region 506 is completely free of any portions of the first source structure 526a and the second source structure 526b. For example, following formation of a source material vertically neighboring the stack structure 515, portions of the source material within the horizontal area of the staircase region 506 may be substantially completely removed (e.g., etched away) to form the first source structure 526a, the second source structure 526b. In additional embodiments, portions of the first source structure 526a and the second source structure 526b may extending into the horizontal area of the staircase region 506, but an additional isolation structure within the horizontal area of the staircase region 506 may be formed to intervene between and electrically isolate the first source structure 526a and the second source structure 526b from one another. For example, vertical heights of portions of the first source structure 526a and the second source structure 526b within the horizontal area of the staircase region 506 may be smaller than vertical heights of additional portions of the first source structure 526a and the second source structure 526b within the horizontal areas of the first memory cell region 504a and the second memory cell region 504b; and an isolation structure within the horizontal area of the staircase region 506 may intervene between and electrically isolate the portions of the first source structure 526a and the second source structure 526b within the horizontal area of the staircase region 506 from one another.

The microelectronic device structure 500 may further include conductive contact structures 532 extending vertically (e.g., Z-direction) through the stack structure 515. The conductive contact structures 532 may individually connect to the conductive material 516 of a respective one of the tiers 520 of the stack structure 515. The microelectronic device structure 500 further comprises additional contact structures 538 horizontally overlapping and vertically extending through the staircase region 506. Because the source structures 526 are at least partially (e.g., completely) absent from the staircase region 506, the conductive contact structures 532 and the additional contact structures 538 do not land on the source structures 526. In this embodiment, the conductive contact structures 532 and the additional contact structures 538 may be considered “floating” support structures since they do not land on or electrically contact the source structures 526 or other conductive structures (e.g., conductive islands) within the source tier 519.

Accordingly, in one aspect, a microelectronic device includes a stack structure including tiers vertically stacked relative to one another and respectively including conductive material vertically neighboring insulative material. The stack structure includes two memory array regions and a staircase region horizontally between the two memory array regions. The microelectronic device also includes strings of memory cells within horizontal areas of and vertically extending through the two memory array regions of the stack structure. A source tier is vertically offset from the stack structure and includes source structures in contact with the strings of memory cells. A horizontal area of the staircase region of the stack structure is substantially free of the source structures.

In one aspect, a memory device includes a stack structure having levels of conductive material vertically alternating with levels of insulative material. The stack structure includes a first memory array region, a second memory array region, and a contact region horizontally intervening between the first memory array region and the second memory array region. A first source structure vertically underlies and is substantially confined within a horizontal area of the first memory array region of stack structure. The memory device further includes first cell pillar structures within the horizontal area of and vertically extending through the first memory array region of stack structure. The first cell pillar structures respectively include semiconductor material coupled to the first source structure. The memory device includes a second source structure vertically underlying and substantially confined within a horizontal area of the second memory array region of stack structure, and second cell pillar structures within the horizontal area of and vertically extending through the second memory array region of stack structure. The second cell pillar structures respectively include additional semiconductor material coupled to the second source structure.

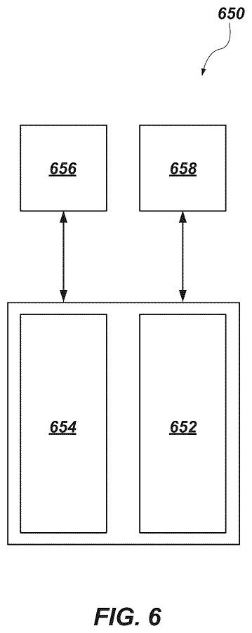

Microelectronic device structures (e.g., the microelectronic device structures 100, 200, 300, 400, 500 previously described with reference to FIGS. 1-5) in accordance with embodiments of the disclosure may be used in embodiments of electronic systems of the disclosure. For example, FIG. 6 is a block diagram of an illustrative electronic system 650 according to embodiments of disclosure. The electronic system 650 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 650 includes at least one memory device. The memory device 652 may include, for example, an embodiment of a microelectronic device structure (e.g., one or more of the microelectronic device structures 100, 200, 300, 400, 500 previously described with reference to FIGS. 1-5) previously described herein. The electronic system 650 may further include at least one electronic signal processor device 654 (often referred to as a “microprocessor”). The electronic signal processor device 654 may, optionally, include an embodiment of a microelectronic device structure (e.g., one or more of the microelectronic device structures 100, 200, 300, 400, 500 previously described with reference to FIGS. 1-5) previously described herein. While the memory device 652 and the electronic signal processor device 654 are depicted as two (2) separate devices in FIG. 6, in additional embodiments, a single (e.g., only one) memory/processor device having the functionalities of the memory device 652 and the electronic signal processor device 654 is included in the electronic system 650. In such embodiments, the memory/processor device may include an embodiment of a microelectronic device structure (e.g., one or more of the microelectronic device structures 100, 200, 300, 400, 500 previously described with reference to FIGS. 1-5) previously described herein.

The electronic system 650 may further include one or more input devices 656 for inputting information into the electronic system 650 by a user, such as, for example, a mouse or other pointing device, a keyboard, a touchpad, a button, or a control panel. The electronic system 650 may further include one or more output devices 658 for outputting information (e.g., visual or audio output) to a user such as, for example, a monitor, a display, a printer, an audio output jack, a speaker, etc. In some embodiments, the input device 656 and the output device 658 may comprise a single touchscreen device that can be used both to input information to the electronic system 650 and to output visual information to a user. The input device 656 and the output device 658 may communicate electrically with one or more of the memory device 652 and the electronic signal processor device 654.

Accordingly, in one aspect, an electronic system includes a processor device operatively associated with an input device and an output device and a memory device operatively associated with the process device. The memory device includes a stack structure having a vertically alternating sequence of conductive material and insulative material arranged in tiers. The stack structure includes a contact region horizontally interposed between a first memory array region and a second memory array region in a first direction. The memory device further includes a source tier vertically offset from the stack structure. The source tier includes a first source structure substantially confined within horizontal boundaries of the first memory array region of the stack structure and a second source structure substantially confined within horizontal boundaries of the second memory array region of the stack structure. The memory device further includes first strings of non-volatile memory cells coupled to the first source structure and vertically extending through the first memory array region of the stack structure and second strings of non-volatile memory cells coupled to the second source structure and vertically extending through the second memory array region of the stack structure. A first source controller is coupled to the first source structure and a second source controller is coupled to the second source structure.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a stack structure comprising tiers vertically stacked relative to one another and respectively including conductive material vertically neighboring insulative material, the stack structure comprising two memory array regions and a staircase region horizontally between the two memory array regions;
strings of memory cells within horizontal areas of and vertically extending through the two memory array regions of the stack structure; and
a source tier vertically offset from the stack structure and comprising source structures in contact with the strings of memory cells, a horizontal area of the staircase region of the stack structure substantially free of the source structures.

2. The microelectronic device of claim 1, further comprising support structures within the horizontal area of the staircase region of stack structure, the support structures vertically extending through the stack structure and the source tier and electrically isolated from the source structures of the source tier.

3. The microelectronic device of claim 1, wherein the source structures of the source tier comprise:
a first source structure vertically underlying and horizontally overlapping a first of the two memory array regions of the stack structure; and
a second source structure vertically underlying and horizontally overlapping a second of the two memory array regions of the stack structure, the second source structure electrically isolated from the first source structure.

4. The microelectronic device of claim 3, further comprising:
a first source controller coupled to the first source structure, the first source controller operable to control a voltage to the first source structure; and
a second source controller coupled to the second source structure, the second source controller operable to control a voltage to the second source structure.

5. The microelectronic device of claim 3, further comprising a string driver within the horizontal area of the staircase region of the stack structure and operably connected to the strings of memory cells within horizontal areas of two memory array regions of the stack structure.

6. The microelectronic device of claim 1, wherein the stack structure further comprises at least one staircase structure within the staircase region thereof, the at least one staircase structure comprising step defined by horizontal ends of the tiers of the stack structure.

7. The microelectronic device of claim 6, further comprising conductive contact structures within the horizontal area of the staircase region of the stack structure, the conductive contact structures individually vertically extending to and contacts the conductive material of a respective one of the tiers of the stack structure.

8. The microelectronic device of claim 7, further comprising conductive routing structures vertically overlying the stack structure and coupled to the conductive contact structures.

9. The microelectronic device of claim 1, further comprising conductive contact structures within the horizontal area of and vertically extending through the staircase region of stack structure, the conductive contact respectively coupled to the conductive material of a respective one of the tiers of the stack structure.

10. A memory device, comprising:
a stack structure comprising levels of conductive material vertically alternating with levels of insulative material, the stack structure comprising:
a first memory array region;
a second memory array region; and
a contact region horizontally intervening between the first memory array region and the second memory array region;
a first source structure vertically underlying and substantially confined within a horizontal area of the first memory array region of stack structure;
first cell pillar structures within the horizontal area of and vertically extending through the first memory array region of stack structure, the first cell pillar structures respectively including semiconductor material coupled to the first source structure;
a second source structure vertically underlying and substantially confined within a horizontal area of the second memory array region of stack structure; and
second cell pillar structures within the horizontal area of and vertically extending through the second memory array region of stack structure, the second cell pillar structures respectively including additional semiconductor material coupled to the second source structure.

11. The memory device of claim 10, further comprising:
a first source controller coupled to the first source structure; and
a second, different source controller coupled to the second source structure.

12. The memory device of claim 11, wherein the second source structure is at a vertical elevation of and is electrically isolated from the first source structure.

13. The memory device of claim 12, further comprising at least one string driver within a horizontal area of the contact region of the stack structure.

14. The memory device of claim 13, wherein the at least one string driver comprises:
a first string driver operatively associated with a first semi-plane of the stack structure; and
a second string driver operatively associated with a second semi-plane of the of the stack structure horizontally offset from the first semi-plane of the stack structure.

15. An electronic system, comprising:
a processor device operatively associated with an input device and an output device; and
a memory device operatively associated with the process device and comprising:
a stack structure comprising a vertically alternating sequence of conductive material and insulative material arranged in tiers, the stack structure comprising a contact region horizontally interposed between a first memory array region and a second memory array region in a first direction;
a source tier vertically offset from the stack structure and comprising:
a first source structure substantially confined within horizontal boundaries of the first memory array region of the stack structure; and
a second source structure substantially confined within horizontal boundaries of the second memory array region of the stack structure;
first strings of non-volatile memory cells coupled to the first source structure and vertically extending through the first memory array region of the stack structure;
second strings of non-volatile memory cells coupled to the second source structure and vertically extending through the second memory array region of the stack structure;
a first source controller coupled to the first source structure; and
a second source controller coupled to the second source structure.

16. The electronic system of claim 15, wherein the source tier is free of any conductive structures having vertical centerlines substantially vertically aligned with vertical centerlines of the first source structure and the second source structure, a staircase region being interposed between the first memory array region and the second memory array region.

17. The electronic system of claim 16, further comprising conductive support structures within a horizontal area of and completely vertically extending through the contact region of the stack structure.

18. The electronic system of claim 17, wherein the conductive support structures vertically terminate within dielectric material vertically overlapping and horizontally interposed between the first source structure and the second source structure of the source tier.

19. The electronic system of claim 17, wherein the memory device further comprises at least one string driver operatively connected to at least some of the first strings of non-volatile memory cells and at least some of the second strings of non-volatile memory cells.

20. The electronic system of claim 19, wherein the at least one string driver comprises two string drivers horizontally overlapping one another in the first direction and horizontally offset from one another in a second direction orthogonal to the first direction.
